(19) United States
(12) Patent Application Publication
(10) Pub. No.: US 2025/0359466 A1
(43) Pub. Date: Nov. 20, 2025

(54) DISPLAY MODULE, METHOD FOR MANUFACTURING THE SAME AND DISPLAY APPARATUS

(71) Applicant: WUHAN TIANMA MICROELECTRONICS CO., LTD. SHANGHAI BRANCH, Shanghai (CN)

(72) Inventor: Guoqing AN, Shanghai (CN)

(21) Appl. No.: 19/286,065

(22) Filed: Jul. 30, 2025

(30) Foreign Application Priority Data
Apr. 2, 2025 (CN) 202510418430.3

(51) Int. Cl. H10K 59/80; H10K 102/00

(52) U.S. Cl. CPC H10K 59/8722; H10K 59/879; H10K 59/8793; H10K 2102/311

(57) ABSTRACT

Provided are a display module, a manufacturing method of the same, and a display apparatus. The display module includes: a display panel having a first curved surface having a first region and a second region surrounding a periphery of the first region; an adhesion layer located in at least a part of the second region; a flexible material layer connected to the first curved surface through the adhesion layer, a cavity being formed between the flexible material layer and first curved surface, and a surface on a side of the flexible material layer away from the first curved surface having a planar region; and a support material filled in the cavity. The display module, manufacturing method, and display apparatus solve the problem that during a lamination process in a curved surface display module, a laminated component is prone to delamination, which leads to a decrease in device reliability.

### CROSS-REFERENCE TO RELATED APPLICATION

The present application claims priority to Chinese Patent Application No. 202510418430.3, filed on Apr. 2, 2025, the content of which is incorporated herein by reference in its entirety.

### TECHNICAL FIELD

The present disclosure relates to the field of display technologies, and in particular, to a display module, a method for manufacturing the same, and a display apparatus.

### BACKGROUND

Organic light emitting diode (OLED) display technology has advantages such as lightness, thinness, and self-illumination. Therefore, OLEDs are widely used in consumer electronics such as wearable devices.

Flexible OLEDs are widely applicable to curved surface display products in wearable display devices due to their bendable characteristics. During a lamination process in a curved surface display module, a flexible material often produces wrinkles when being attached, and a rigid component is unbendable, resulting in a small bonding area with a curved surface display panel, which often causes the rigid component to detach from the curved surface display panel, leading to a decrease in device reliability.

### SUMMARY

The present disclosure provides a display module, a method for manufacturing the same, and a display apparatus to solve the problem in the related art that during a lamination process in a curved surface display module, a laminated component is prone to delamination, which leads to a decrease in device reliability.

According to an aspect of the present disclosure, there is provided a display module, including: a display panel having a first curved surface, where the first curved surface has a first region and a second region surrounding a periphery of the first region; an adhesion layer located in at least a part of the second region; a flexible material layer connected to the first curved surface through the adhesion layer, where a cavity is formed between the flexible material layer and the first curved surface, and a surface on a side of the flexible material layer away from the first curved surface has a planar region; and a support material filled in the cavity.

According to another aspect of the present disclosure, there is provided a method for manufacturing a display module, including steps of:
S1, providing a display panel having a first curved surface, where the first curved surface has a first region and a second region surrounding a periphery of the first region;
S2, disposing an adhesion layer on the first curved surface, so that the adhesion layer is located in at least a part of the second region;
S3, connecting a flexible material layer to the first curved surface through the adhesion layer, so that a cavity is formed between the flexible material layer and the first curved surface; and
S4, filling a support material into the cavity, so that a surface on a side of the flexible material layer away from the first curved surface has a planar region.

According to yet another aspect of the present disclosure, there is provided a display apparatus including the above-mentioned display module.

The present disclosure provides a display module, including a display panel, an adhesion layer, a flexible material layer, and a cavity. The flexible material layer is bonded to a portion of a first curved surface of the display panel through the adhesion layer, and a cavity is formed in an unbonded region. The cavity enables a side of the flexible material away from the first curved surface to have a planar region. A support material is filled in the cavity to further support the flexible material, making the flexible material less prone to producing wrinkles. Subsequently, after components such as a circuit board and a rigid chip are laminated to the above-mentioned planar region, the flat flexible material ensures the contact area when the components such as a circuit board and a rigid chip are laminated, ensures the adhesive force between the flexible material and the components such as a circuit board and a rigid chip, effectively avoids a decrease in device reliability caused by delamination after the assemblies are attached to the flexible material, and thus solves the problem in the related art that in a lamination process in a curved surface display module, a laminated component is prone to delamination, leading to a decrease in device reliability.

### BRIEF DESCRIPTION OF DRAWINGS

The drawings, which constitute a part of the present disclosure, are used to provide a further understanding of the present disclosure, and the illustrative embodiments and description of the present disclosure are used to explain the present disclosure, and do not constitute an improper limitation on the present disclosure. In the drawings:

FIG. 1 is a schematic diagram of a partial cross-sectional structure of a display module provided by an embodiment of the present disclosure;

FIG. 2 is a schematic diagram of a partial cross-sectional structure of another display module provided by an embodiment of the present disclosure;

FIG. 3 is a schematic diagram of a partial cross-sectional structure of yet another display module provided by an embodiment of the present disclosure;

FIG. 4 is a schematic diagram of a partial top view structure of a display module provided by an embodiment of the present disclosure;

FIG. 5 is a schematic diagram of a partial top view structure of another display module provided by an embodiment of the present disclosure;

FIG. 6 is a schematic diagram of a partial cross-sectional structure of a display module provided with a sensing module and a flexible circuit board provided by an embodiment of the present disclosure;

FIG. 7 is a schematic diagram of a partial cross-sectional structure of a display module provided with a flexible optical film layer provided by an embodiment of the present disclosure;

FIG. 8 is a schematic flow diagram of a method for manufacturing a display module provided by an embodiment of the present disclosure;

FIG. 9 is a schematic flow diagram of an operation step of filling a support material into a cavity provided by an embodiment of the present disclosure;

FIG. 10 is a schematic flow diagram of a method for manufacturing a display panel provided by an embodiment of the present disclosure;

FIG. 11 is a schematic flow diagram of another method for manufacturing a display module provided by an embodiment of the present disclosure; and

FIG. 12 is a structural schematic diagram of a display apparatus provided by an embodiment of the present disclosure.

Where the above drawings include the following reference signs:
1. display apparatus; 2. non-display region; 3. display region; 10. display panel; 11. first curved surface; 12. second curved surface; 20. adhesion layer; 30. flexible material layer; 31. first surface; 32. second surface; 40. cavity; 50. support layer; 61. feed hole; 62. vent hole; 70. sensing module; 80. flexible circuit board; 90. flexible optical film layer; 91. lens layer; 910. third curved surface; 92. polarizing layer.

### DESCRIPTION OF EMBODIMENTS

It should be noted that embodiments of the present disclosure and features in the embodiments may be combined with each other without conflict. The present disclosure will be described in detail below with reference to the drawings and in conjunction with the embodiments.

In order to enable those of skill in the art to better understand the solutions of the present disclosure, the technical solutions in the embodiments of the present disclosure will be clearly and completely described below in conjunction with the drawings in the embodiments of the present disclosure. Apparently, the described embodiments are only a part of the embodiments of the present disclosure, rather than all of them. Based on the embodiments of the present disclosure, all other embodiments obtained by those of ordinary skill in the art without creative efforts shall fall within the protection scope of the present disclosure.

It should be noted that the terms “first”, “second” and the like in the description, claims and drawings of the present disclosure are used to distinguish similar objects, and are not necessarily used to describe a specific order or sequence. It should be understood that the terms used in this way may be interchanged under appropriate circumstances, so as to describe the embodiments of the present disclosure herein. Furthermore, the terms “include”, “have” and any variations thereof are intended to cover non-exclusive inclusion, e.g., processes, methods, systems, products or devices that include a series of steps or units are not necessarily limited to those steps or units that are expressly listed, but may include other steps or units not expressly listed or inherent to such processes, methods, products or devices.

As stated in the background, during a process of laminating a flexible material in a curved surface display module, the flexible material is prone to produce wrinkles, and a rigid component attached to the flexible material is unbendable, so that gaps easily exists between the flexible material and the rigid component, leading to insecure attachment, which in turn causes the rigid component to be prone to detachment from a curved surface display panel, resulting in a decrease in device reliability. In order to solve the above-mentioned problem, the present disclosure provides a display module, a method for manufacturing the same, and a display apparatus.

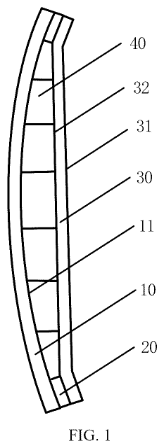

According to an embodiment of the present disclosure, as shown in FIG. 1, there is provided a display module, including a display panel 10, an adhesion layer 20, a flexible material layer 30, and a support material. The display panel 10 has a first curved surface 11 having a first region and a second region surrounding a periphery of the first region; the adhesion layer 20 is located in at least a part of the second region; the flexible material layer 30 is connected to the first curved surface 11 through the adhesion layer 20, and a cavity 40 is formed between the flexible material layer 30 and the first curved surface 11, and a surface on a side of the flexible material layer 30 away from the first curved surface 11 has a planar region; and the support material is filled in the cavity 40.

According to the display module in the above-mentioned embodiment, as shown in FIG. 1, the flexible material layer 30 is adhered to the first curved surface 11 of the display panel 10 through the adhesion layer 20 in the second region. Since the adhesion layer 20 is located in at least a part of the second region, a gap is formed between the first region of the first curved surface 11 of the display panel 10 as well as the part of the second region of the display panel 10 that is not covered by the adhesion layer 20 and the flexible material layer 30, and then the cavity 40 is formed. The cavity 40 is filled with the support material to support the flexible material layer 30, so that the surface on the side of the flexible material layer 30 away from the first curved surface 11 has the planar region. The planar region ensures that components such as a circuit board and a rigid chip will be tightly laminated to the planar region subsequently, thereby avoiding the formation of gaps, effectively avoiding a decrease in device reliability caused by delamination after lamination of the components, improving the overall stability and durability of the display module, and solving the problem in the related art that during a lamination process in a curved surface display module, a laminated component is prone to delamination, which leads to a decrease in device reliability.

The above is the core idea of the present disclosure, and the following will clearly and completely describe the technical solutions in the embodiments of the present disclosure in conjunction with the drawings in the embodiments of the present disclosure. Based on the embodiments of the present disclosure, all other embodiments obtained by those of ordinary skill in the art without creative efforts shall fall within the protection scope of the present disclosure.

In the display module in the embodiment of the present disclosure, the support material includes a cured product formed from a thermosetting resin. The support material formed after curing of the thermosetting resin has higher hardness and stability, and can effectively support the flexible material layer, so as to maintain the planar region on the surface on the side of the flexible material layer away from the first curved surface, avoiding deformation thereof in the process of use, thereby ensuring the structural integrity and display effect of the display module.

Specifically, the thermosetting resin includes but is not limited to one or more of epoxy resin, acrylate resin, polyurethane resin, and UV curing resin, and those of skill in the art can select the material(s) according to actual needs.

In some optional implementations, a minimum curing temperature of the thermosetting resin is less than or equal to 50° C. A lower curing temperature can avoid thermal damage to other assemblies in the display module and thus the decreased performance of the display panel, thereby ensuring the performance and service life of the display panel, and at the same time reducing energy consumption in the production process and improving production efficiency.

In some optional implementations, a material of the flexible material layer includes foamed plastic particles. The foamed plastic particles have characteristics such as light weight, heat insulation, and sound insulation, which can effectively reduce the weight of the display module while providing good heat insulation and sound insulation effects, improving the portability and use comfort of the display module.

In some optional implementations, the plastic particles are selected from one or more of polyethylene (PE), polypropylene (PP), and polystyrene (PS), but are not limited to the above-mentioned types. The use of plastic particles of a higher hardness type can play a supportive role for the flexible support layer, and avoid damage during an adhesion process. While the use of plastic particles of a lower hardness type can effectively reduce the weight of the display module and is less likely to break when subjected to an external force. Those of skill in the art should select suitable plastic particles according to specific actual needs.

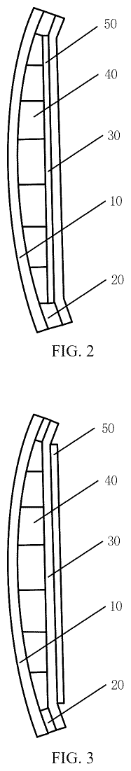

In some optional implementations, as shown in FIG. 2, the display module further includes a support layer 50 located on a side of the flexible material layer 30 close to the first curved surface; or as shown in FIG. 3, the display module further includes a support layer 50 located on a side of the flexible material layer 30 away from the first curved surface. A hardness of the support layer 50 is greater than a hardness of the flexible material layer 30. As shown in FIGS. 2 and 3, the provision of the support layer 50 can further enhance the structural stability of the display module, especially in the curved surface portion of the display panel 10, which can not only play a supportive role for the flexible support layer 50 and prevent the deformation of the flexible support layer 50, but also effectively prevent deformation due to the action of an external force, improving the impact resistance of the display module. FIGS. 2 and 3 also show an adhesion layer 20 and a cavity 40. The description of the adhesion layer 20 and the cavity 40 is referred to the description in the above-mentioned embodiment and will not be repeated herein.

In some optional implementations, as shown in FIG. 1, the surface of the flexible material layer 30 having the planar region is a first surface 31, and at least a part of the planar region is located at an edge of the first surface 31. Such a design enables the display module to have a planar structure in an edge region, which facilitates connection and fixation with an edge assembly, including a rigid chip provided from the edge, such as NFC, etc. Having the planar structure in the edge region increases the attachment area of the edge assembly, thereby improving the assembly efficiency and structural integrity of the display module.

In some optional implementations, as shown in FIG. 1, the first surface 31 is planar. The first surface 31 is a whole plane, and the whole planar first surface 31 improves the flatness between the first surface 31 and a subsequently adhered assembly compared to a partially planar first surface 31, thereby improving the reliability of the first surface 31 and the subsequently adhered assembly. The above-mentioned design can not only facilitate the connection with other assemblies, but also provide a better touch operation experience, avoiding the problem of inaccurate touch caused by a curved surface design.

In some optional implementations, as shown in FIG. 1, a surface on the side of the flexible material layer 30 close to the first curved surface 11 is a second surface 32, and the second surface 32 is planar. The fact that the second surface 32 is also planar ensures the flatness and uniformity of the support material filling, and is conducive to ensuring the flatness of the first surface 31 after the support material is injected, which in turn ensures the adhesion reliability of other assemblies.

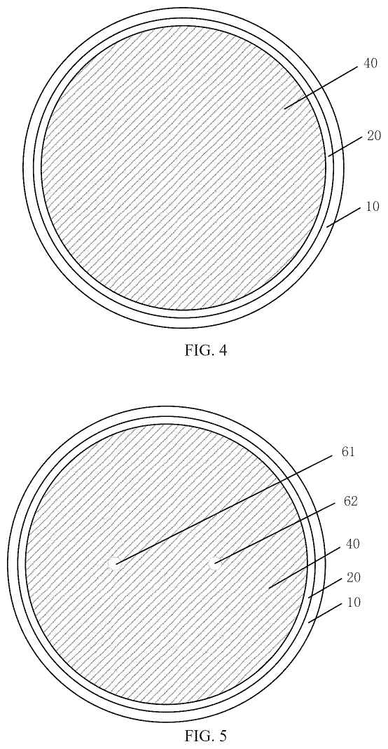

In some optional implementations, as shown in FIGS. 1 and 4, the adhesion layer 20 is disposed at an edge of the first curved surface 11 in a surrounding manner. The adhesion layer 20 disposed in a surrounding manner can provide uniform adhesive force, ensuring a tight connection between the flexible material layer 30 and the display panel 10, and avoiding problems such as structural loosening or damage caused by insufficient local adhesive force. The adhesion layer 20 disposed in a surrounding manner ensures that the cavity 40 between the first surface 31 and the flexible material layer 30 has the same shape at an upper edge of the flexible material layer 30 as the shape of an edge of the display panel 10. The consistency of the edge shapes ensures the uniformity of the injected support material, and in turn ensures the flatness of the first surface 31, avoiding gaps formed when the first surface 31 is adhered to other assemblies, and improving the structural stability and reliability of the display module.

Specifically, a material of the adhesion layer can be selected from one or more of acrylic adhesive, silicone adhesive, polyethylene terephthalate (PET), polyethylene (PE)-based adhesive tape, polyvinyl chloride (PVC)-based adhesive tape, and foam adhesive tape, but is not limited to the above-mentioned types, and those of skill in the art can make a reasonable selection based on the prior art.

In some optional implementations, as shown in FIGS. 1 and 5, the flexible material layer 30 has a feed hole 61 and a vent hole 62. The provision of the feed hole 61 and the vent hole 62 can achieve accurate filling of the support material, avoiding the problem of bubbles or uneven filling during a filling process, and ensuring that the first surface 31 is planar, thereby avoiding gaps formed when the first surface 31 is adhered to other assemblies, and improving the structural integrity and display effect of the display module. FIG. 5 further shows a display panel 10, an adhesion layer 20, and a cavity 40. The description of the display panel 10, the adhesion layer 20, and the cavity 40 is referred to the description in the above-mentioned embodiments and will not be repeated herein.

In some optional implementations, as shown in FIG. 6, the display module further includes a sensing module 70 and a flexible circuit board 80. The sensing module 70 is in contact with the planar region, and the flexible circuit board 80 is located on a side of the sensing module 70 away from the planar region. The provision of the sensing module 70 and the flexible circuit board 80 can realize the touch function of the display module, improving the interactivity and user experience of the display apparatus. The sensing module 70 includes but is not limited to a module such as NFC. FIG. 6 further shows a display panel 10, an adhesion layer 20, a flexible material layer 30, and a cavity 40. The description of the display panel 10, the adhesion layer 20, the flexible material layer 30, and the cavity 40 is referred to the description in the above-mentioned embodiments and will not be repeated herein.

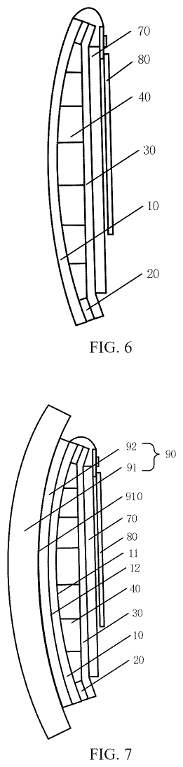

In some optional implementations, as shown in FIG. 7, the display module further includes a lens layer 91 located on a light exit side of the display panel 10. The lens layer 91 has a third curved surface 910, and both the third curved surface 910 and the first curved surface 11 are recessed toward the light exit side of the display panel 10. The provision of the lens layer 91 can improve the light emitting effect of the display panel 10, enhance the definition of an image, reduce the edge distortion of an image, improve the contrast, improve the color saturation, expand the viewing angle range of the display module, and improve the display quality and visual effect of the display module.

In some optional implementations, as shown in FIG. 7, the display panel 10 has a second curved surface 12 opposite to the first curved surface 11, and the second curved surface 12 bulges toward the light exit side of the display panel 10. A flexible optical film layer 90 includes the lens layer 91 and a polarizing layer 92. The lens layer 91 has a third curved surface 910, and the polarizing layer 92 is located between the third curved surface 910 and the second curved surface 12. The polarizing layer 92 can absorb a part of the natural light incident from the outside, so that the readability and contrast of the display panel is improved, and at the same time, the contrast and color saturation of the display module is improved, providing a more realistic display effect. FIG. 7 further shows a display panel 10, an adhesion layer 20, a flexible material layer 30, a cavity 40, a sensing module 70, and a flexible circuit board 80. The description of the above-mentioned structure is referred to the description in the above-mentioned embodiments and will not be repeated herein.

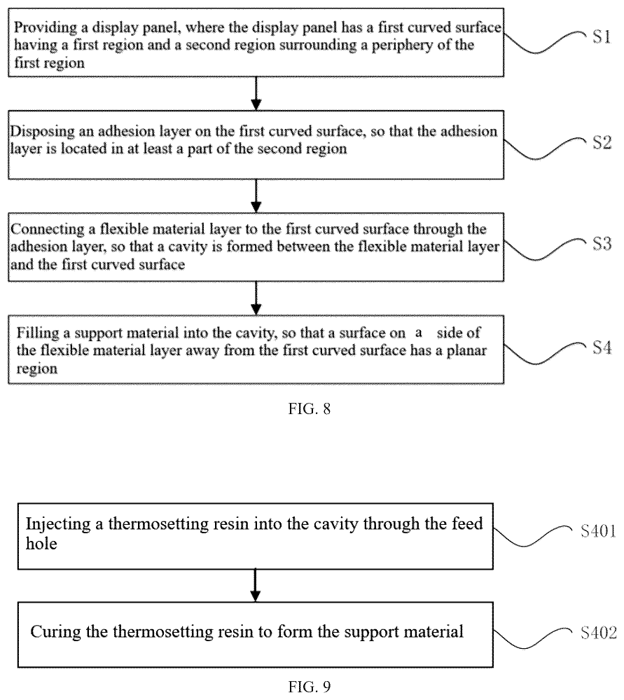

According to another aspect of the present disclosure, there is provided a method for manufacturing a display module, as shown in FIG. 8, including steps of:
S1: providing a display panel, where the display panel has a first curved surface having a first region and a second region surrounding a periphery of the first region;
S2, disposing an adhesion layer on the first curved surface, so that the adhesion layer is located in at least a part of the second region;
S3, connecting a flexible material layer to the first curved surface through the adhesion layer, so that a cavity is formed between the flexible material layer and the first curved surface; and
S4, filling a support material into the cavity, so that a surface on a side of the flexible material layer away from the first curved surface has a planar region.

Through the above-mentioned implementation, the display module as shown in FIG. 1 is formed. The cavity 40 is formed between the flexible material layer 30 and the first curved surface 11 of the display panel 10 through the adhesion layer 20, and the cavity 40 is filled with the support material, so that the surface on the side of the flexible material layer 30 away from the first curved surface 11 has the planar region. After components such as a circuit board and a rigid chip are laminated to the planar region, the flexible circuit board and the rigid chip can be tightly laminated to the planar region, avoiding the formation of gaps, which can effectively avoid a decrease in device reliability caused by delamination after lamination of the components, improving the overall stability and durability of the display module, and solving the problem in the related art that during a lamination process in a curved surface display module, a laminated component is prone to delamination, which leads to a decrease in device reliability.

Exemplary implementations of the method for manufacturing a display module provided by the present disclosure will be described in more detail below. However, these exemplary implementations may be implemented in a number of different forms and should not be construed as being limited to the implementations set forth herein. It should be understood that these implementations are provided to make the disclosure of the present disclosure thorough and complete, and to fully convey the concepts of these exemplary implementations to those of ordinary skill in the art.

First, the step S1 is performed: providing a display panel, where the display panel has a first curved surface having a first region and a second region surrounding a periphery of the first region.

Specifically, types of the display panel include but are not limited to a curved surface LCD panel, a curved surface OLED panel, a curved surface AMOLED panel, a curved surface quantum dot display panel, a curved surface Micro LED panel, etc., and those of skill in the art can select a suitable panel according to actual situations.

After the display panel is provided, the step S2 is performed: disposing an adhesion layer on the first curved surface, so that the adhesion layer is located in at least a part of the second region.

The adhesion layer is located in at least a part of the second region, to allow a gap to be formed between the flexible material layer subsequently adhered to the first surface and the portion of the first surface.

Specifically, a material of the adhesion layer includes but is not limited to acrylic adhesive, silicone adhesive, polyethylene terephthalate (PET), polyethylene (PE)-based adhesive tape, polyvinyl chloride (PVC)-based adhesive tape, foam adhesive tape and the like, and those of skill in the art can select a suitable adhesion layer material according to actual needs.

After the adhesion layer is disposed on the surface of the first curved surface, the step S3 is performed: connecting a flexible material layer to the first curved surface through the adhesion layer, so that a cavity is formed between the flexible material layer and the first curved surface.

The cavity is formed between the flexible material and the first curved surface. Since the shape of the flexible material is variable, wrinkles are easily produced after the flexible material is completely attached to the first curved surface, leading to gaps formed between a subsequently adhered rigid component and the flexible material and thus the detachment of the component. Instead, by partially adhering the flexible material to the first curved surface to form the cavity with the first curved surface, it can be ensured that a part of the flexible material is planar after being adhered. This part of the flexible material does not produce wrinkles, ensuring the reliability of adhesion of a rigid component subsequently adhered to this planar part of the flexible material.

Specifically, a material of the flexible material layer can include foamed plastic particles. Exemplarily, the plastic particles are selected from one or more of polyethylene (PE), polypropylene (PP), and polystyrene (PS).

After the cavity is formed between the flexible material layer and the first curved surface, the step S4 is performed: filling a support material into the cavity, so that a surface on a side of the flexible material layer away from the first curved surface has a planar region.

An unfilled cavity, due to the variable shape of the flexible material forming the cavity, is prone to deformation after being subjected to compression, vibration, and other conditions, causing an assembly subsequently adhered to the flexible material to separate from the flexible material. By filling the support material into the cavity to support the flexible material and keep the flexible material in a planar state, the reliability of the subsequently adhered rigid assembly is ensured.

The display module manufactured by the above-mentioned steps, as shown in FIG. 1, includes: the display panel 10, the adhesion layer 20, the flexible material layer 30, and the support material. The display panel 10 and the flexible material are partially bonded to each other through the adhesion layer 20 to form the cavity 40, and the support material is filled into the cavity 40.

In some optional implementations, as shown in FIG. 9, the flexible material layer has a feed hole 61 and a vent hole 62, and the structures thereof are shown in FIG. 5. The step of filling a support material into the cavity includes:

S401, injecting a thermosetting resin into the cavity through the feed hole; and S402, curing the thermosetting resin to form the support material.

This precise filling method can avoid the problem of bubbles or uneven filling during a filling process, improving the structural integrity and display effect of the display module.

Specifically, the thermosetting resin includes but is not limited to one or more of epoxy resin, acrylate resin, polyurethane resin, and UV curing resin, and those of skill in the art can select the material(s) according to actual needs.

In some optional implementations, the thermosetting resin is cured at a temperature of 40° C. to 50° C. A lower curing temperature can avoid thermal damage to other assemblies in the display module and thus the decreased performance of the display panel, thereby ensuring the performance and service life of the display panel, and at the same time reducing energy consumption in the production process and improving production efficiency.

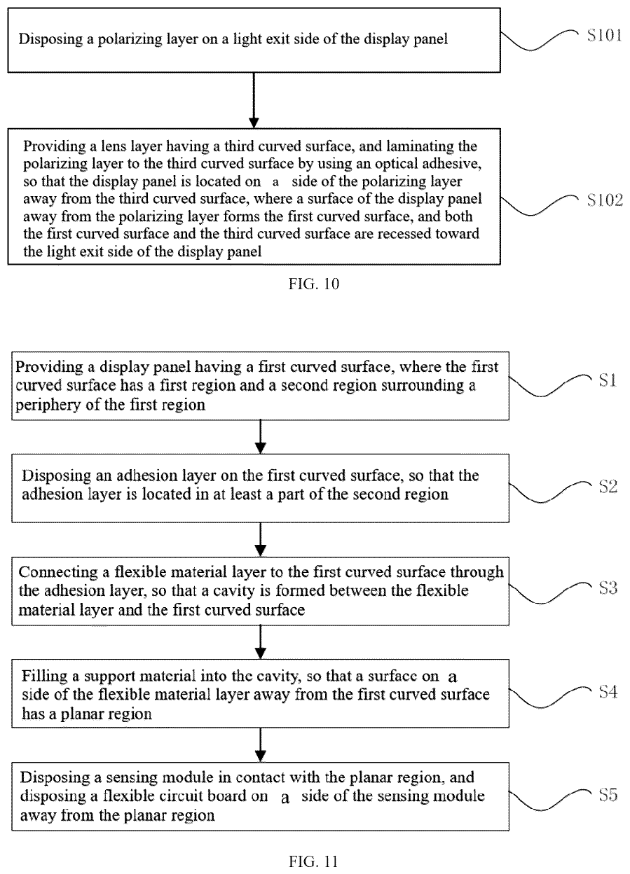

In some optional implementations, as shown in FIG. 10, the step of providing a display panel includes:

S101, disposing a polarizing layer on a light exit side of the display panel; and S102, providing a lens layer having a third curved surface, and laminating the polarizing layer to the third curved surface by using an optical adhesive, so that the display panel is located on a side of the polarizing layer away from the third curved surface, where a surface of the display panel away from the polarizing layer forms the first curved surface, and both the first curved surface and the third curved surface are recessed toward the light exit side of the display panel.

In a curved surface display apparatus, the lens layer can optimize the light distribution according to the shape of its curved surface, to reduce the edge distortion, improve the brightness and contrast of the display apparatus, and help expand the effective viewing angle range, so that the quality of an image remains consistent when being viewed at different angles.

By laminating the polarizing layer to the third curved surface, it can not only improve the light emitting effect of the display panel, but also effectively filter stray light, enhancing the contrast and color saturation of the display module, providing a more realistic display effect, and at the same time, reducing the thickness and weight of the apparatus.

In some optional implementations, as shown in FIG. 11, the above-mentioned manufacturing method in the embodiments of the present disclosure further includes, after the step of filling a support material into the cavity:

S5, disposing a sensing module in contact with the planar region, and disposing a flexible circuit board on a side of the sensing module away from the planar region.

The display module manufactured by the above-mentioned steps, as shown in FIGS. 5 and 7, includes: the lens layer 91, the polarizing layer 92, the display panel 10, the adhesion layer 20, the cavity 40, the flexible material layer 30, the sensing module 70, the flexible circuit board 80 disposed along a first direction, and the display module further includes the feed hole 61 and the vent hole 62 disposed on the flexible material layer 30.

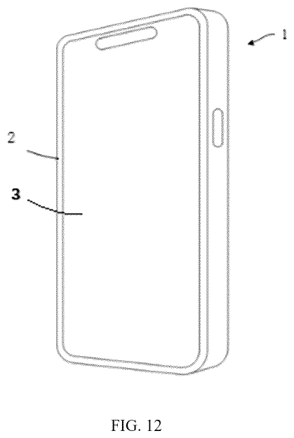

According to yet another aspect of the present disclosure, there is provided a display apparatus. As shown in FIG. 12, the display apparatus 1 includes the display module described above. The display panel in the display module has a display region 3 and a non-display region 2.

Specifically, the above-mentioned display apparatus may be an electronic device such as a mobile phone, a computer, and a television, and the display panel may be applied thereto. Components such as a circuit board and a rigid chip are tightly laminated to the flexible material layer, and the support material injected between the display panel and the flexible material layer provides support for the flexible material, avoid the flexible material producing wrinkles, and effectively avoiding a decrease in device reliability caused by delamination after lamination of the components, improving the structural stability and the display effect of the display apparatus.

From the above description, it can be seen that the above-mentioned embodiments of the present disclosure achieve the following technical effects:

1) According to the present disclosure, the cavity is formed between the display panel and the flexible material layer, and the cavity is filled with the support material to support the flexible material layer, so that the surface on the side of the flexible material layer away from the first curved surface has the planar region, which ensures that components such as a circuit board and a rigid chip will be tightly laminated to the planar region subsequently, thereby avoiding the formation of gaps between the components such as a circuit board and a rigid chip and the flexible material, which can effectively avoid a decrease in device reliability caused by delamination after lamination of the components, improving the overall stability and durability of the display module, and solving the problem in the related art that during a lamination process in a curved surface display module, a laminated component is prone to delamination, which leads to a decrease in device reliability.

2) The present disclosure can optimize the design of the support structure. By disposing the support layer to further support the flexible material layer, the deformation of the flexible material layer is greatly reduced, avoiding the formation of gaps between a subsequently adhered circuit board, rigid chip and the like and the flexible material layer due to wrinkles produced in the flexible material layer, thereby improving the device reliability.

It should be further noted that, the terms such as “include”, “comprise” or any other variations thereof are intended to cover non-exclusive inclusion, so that a process, method, article, or device including a series of elements not only includes those elements, but also includes other elements not explicitly listed, or further includes elements inherent to such a process, method, article, or device. Without more limitations, an element defined by the phrase “including a . . . ” does not preclude the presence of additional identical elements in the process, method, article, or device that includes the element.

The above are only the embodiments of the present disclosure and are not intended to limit the present disclosure. For those of skill in the art, the present disclosure is susceptible to various modifications and changes. Any modification, equivalent substitution, improvement, etc., made within the spirit and principle of the present disclosure shall be included within the scope of the claims of the present disclosure.

What is claimed is:

1. A display module, comprising:
a display panel having a first curved surface, wherein the first curved surface has a first region and a second region surrounding a periphery of the first region;
an adhesion layer located in at least a part of the second region;
a flexible material layer connected to the first curved surface through the adhesion layer, wherein a cavity is formed between the flexible material layer and the first curved surface, and a surface on a side of the flexible material layer away from the first curved surface has a planar region; and
a support material filled in the cavity.

2. The display module according to claim 1, wherein the support material comprises a cured product formed from a thermosetting resin.

3. The display module according to claim 2, wherein a minimum curing temperature of the thermosetting resin is less than or equal to 50° C.

4. The display module according to claim 1, wherein a material of the flexible material layer comprises foamed plastic particles.

5. The display module according to claim 4, wherein the plastic particles are selected from one or more of polyethylene, polypropylene, and polystyrene.

6. The display module according to claim 4, further comprising a support layer located on a side of the flexible material layer close to or away from the first curved surface, wherein a hardness of the support layer is greater than a hardness of the flexible material layer.

7. The display module according claim 1, wherein the surface of the flexible material layer having the planar region is a first surface, and at least a part of the planar region is located at an edge of the first surface.

8. The display module according to claim 7, wherein the first surface is planar.

9. The display module according to claim 8, wherein a surface of the flexible material layer close to the first curved surface is a second surface, and the second surface is planar.

10. The display module according to claim 1, wherein the adhesion layer is disposed at an edge of the first curved surface in a surrounding manner.

11. The display module according to claim 1, wherein the flexible material layer has a feed hole and a vent hole.

12. The display module according to claim 1, further comprising a sensing module and a flexible circuit board, wherein the sensing module is in contact with the planar region, and the flexible circuit board is located on a side of the sensing module away from the planar region.

13. The display module according to claim 1, further comprising a lens layer located on a light exit side of the display panel, wherein the lens layer has a third curved surface, and both the third curved surface and the first curved surface are recessed toward the light exit side of the display panel.

14. The display module according to claim 13, wherein the display panel has a second curved surface opposite to the first curved surface, the second curved surface bulges toward the light exit side of the display panel, a flexible optical film layer comprises the lens layer and a polarizing layer, the lens layer has the third curved surface, and the polarizing layer is located between the third curved surface and the second curved surface.

15. A method for manufacturing a display module, comprising steps of:
providing a display panel having a first curved surface, wherein the first curved surface has a first region and a second region surrounding a periphery of the first region;
disposing an adhesion layer on the first curved surface, so that the adhesion layer is located in at least a part of the second region;
connecting a flexible material layer to the first curved surface through the adhesion layer, so that a cavity is formed between the flexible material layer and the first curved surface; and
filling a support material into the cavity, so that a surface on a side of the flexible material layer away from the first curved surface has a planar region.

16. The manufacturing method according to claim 15, wherein the flexible material layer has a feed hole and a vent hole, and the step of filling a support material into the cavity comprises:
injecting a thermosetting resin into the cavity through the feed hole; and
curing the thermosetting resin to form the support material.

17. The manufacturing method according to claim 16, wherein the thermosetting resin is cured at a temperature of 40° C. to 50° C.

18. The manufacturing method according to claim 16, wherein the step of providing a display panel comprises:
disposing a polarizing layer on a light exit side of the display panel; and
providing a lens layer having a third curved surface, and laminating the polarizing layer to the third curved surface by using an optical adhesive, so that the display panel is located on a side of the polarizing layer away from the third curved surface, wherein a surface of the display panel away from the polarizing layer forms the first curved surface, and both the first curved surface and the third curved surface are recessed toward the light exit side of the display panel.

19. The manufacturing method according to claim 16, further comprises, after the step of filling a support material into the cavity:
disposing a sensing module in contact with the planar region, and disposing a flexible circuit board on a side of the sensing module away from the planar region.

20. A display apparatus, comprising a display module, wherein the display module comprises:
a display panel having a first curved surface, wherein the first curved surface has a first region and a second region surrounding a periphery of the first region;
an adhesion layer located in at least a part of the second region;
a flexible material layer connected to the first curved surface through the adhesion layer, wherein a cavity is formed between the flexible material layer and the first curved surface, and a surface on a side of the flexible material layer away from the first curved surface has a planar region; and
a support material filled in the cavity.
